(19) United States
(12) Patent Application Publication
(10) Pub. No.: US 2026/0032834 A1
(43) Pub. Date: Jan. 29, 2026

(54) CONTROLLER INTERFACE AND PROCESS FOR ASSEMBLY THEREOF

(71) Applicant: CAREL INDUSTRIES S.p.A., Brugine (PD) (IT)

(72) Inventors: Paolo MARAFIN, Brugine (PD) (IT); Chiara MILANI, Brugine (PD) (IT)

(21) Appl. No.: 19/143,626

(22) PCT Filed: Dec. 22, 2023
(86) PCT No.: PCT/IB2023/063173

§ 371 Date: Jun. 26, 2025

(30) Foreign Application Priority Data
Dec. 27, 2022 (IT) 102022000026856

(51) Int. Cl. H05K 5/02

(52) U.S. Cl. CPC H05K 5/0217

(57) ABSTRACT

Controller interface (100) comprising;—a screen (110) having a front face (110a) and a back face (110a) and comprising an operative layer (111) having pads (111a) and a plurality of first contacts (111b) for forming a touch screen;—an electronic device (120) having a plurality of second contacts (120a);—a frame (130) for supporting the screen (110) and the electronic device (120). The frame (130) has through-openings (130a) each corresponding to a first contact (111b) which defines a portion. The electronic device (120) is configured so that the second contacts are positioned so as to face the first contacts (111b) through the openings (130a). A conductive adhesive (140) connects each first contact (11b) to the corresponding second contact through the respective opening (130a) of the frame (130).

### TECHNICAL SECTOR

The present invention relates to an interface for a controller and to a process for assembly thereof.

### PRIOR ART

The prior art known to the Applicant at the time of filing of the present application is briefly described in this section.

Said prior art may therefore not be regarded per se as being publicly accessible either in the combination of information which forms it or in terms of each of its aspects considered singly.

Nowadays, in the sector of interfaces for operating a controller, particularly well-known are the interfaces known as “touch screens”, i.e. where interaction with the interface is possible simply by touching its screen on which icons or symbols indicating the functions of the controller are displayed to the operator.

Generally this type of interface comprises an upper layer, or screen, which in turn incorporates an electronic circuit provided with pads apt to be activated by means of pressure, i.e. able to be operated by means of a user touching them.

The screen, in accordance with the patent IT102019000023187 in the name of the same Applicant may comprise a set of operative layers, also known as an “overlay”.

The overlay may comprise an outer, transparent, protective layer, for example made of polycarbonate, a graphics layer, namely a layer apt to define the external appearance of the interface as visible through the protective layer, a possible diffusion layer, apt to ensure uniform backlighting of the graphics layer, and a masking layer which is impermeable to the luminous backlighting so as to form symbols and/or numbers to be displayed to an operator.

The interface comprises a frame designed to support the screen and a PCB, namely an electronic circuit which constitutes the operative part of the interface which may be integrated with the said controller.

An operative layer comprising the electronic circuit provided with pads for detecting the pressure may be fixed to the overlay, at the rear, namely on the face opposite to the protective layer.

These pads are electronically connected to a terminal of the electronic circuit of the operative layer, provided with first contacts.

The connection between the electronic circuit of the screen and the PCB is performed by means of the terminal which extends from the electronic circuit of the screen and which is designed to be connected with second contacts provided in a PCB socket, as shown in FIGS. 1a and 1b.

For assembly of a conventional interface, it is therefore necessary to connect the terminal of the electric circuit of the screen with the PCB socket and then the screen may be fixed to the frame in order to support it, or vice versa.

Thus the device composed of the screen, the frame and the PCB may be assembled to form the interface of a controller which can be installed on a machine in order to operate it.

However, this solution is complex in terms of assembly and is not always able to ensure a reliable electrical connection between the first contacts and the second contacts and the possibility of providing an interface certified as suitable for operation in environments with an atmosphere which may adversely affect the efficiency of the electrical contacts, as when used in refrigerating cabinets for cooling bottles, i.e. bottle coolers, where oxidation of the electrical contacts tends to occur.

Nowadays, in order to ensure an efficient electrical connection between the first contacts, the screen and the second contacts of the PCB, elastic elements made of electrically conductive elastomeric material may be inserted into the PCB socket and pressed onto the second contacts.

However, the process for the production of interfaces constructed in this manner is complex since it requires precise and homogeneous dimensions of the elastic elements so as to ensure that they both form a reliable conductive bridge between the second contacts and the first contacts, once the terminal is inserted inside the PCB socket, but also do not result in an excessive complexity as regards insertion of said elastic elements into the socket and coupling of the terminal to the said socket.

With particular reference to the present invention, the controller in question is configured to operate an apparatus comprising a refrigerating machine, for example a vending machine, a bottle cooler, a cooling tank and/or a cooled display unit.

### SUMMARY OF THE INVENTION

The problem underlying the present invention is therefore to simplify in structural terms the conventional controllers and their assembly process.

The task of a controller interface and the process for assembly thereof is therefore to solve this problem.

In connection with this task, one object of the invention is to propose a controller interface and the process for assembly thereof, able to ensure a very efficient electrical connection between the interface and the PCB, while simplifying the assembly thereof.

Another object of the invention is to provide a controller interface and a process for assembly thereof, which is able to obtain an interface suitable for reliable and durable operation also in environments with a hostile atmosphere.

Yet another object of the invention is to propose a controller interface which is simple to assemble, reducing the mechanical stresses during assembly of the components, compared to conventional interfaces.

A further object of the invention is to provide a controller interface and the process for assembly thereof which may be easily realized using products and technologies which are known per se, reliable and easy to use.

Yet another object of the present invention is to provide a controller interface and the process for assembly thereof able to ensure a greater protection, compared to conventional solutions, of the electrical contacts between the screen and the PCB.

Another object of the present invention is to propose a controller interface and the process for assembly thereof which is structurally simple, such that a greater duration in efficiency is obtained, compared to the currently known solutions, for the same conditions of use.

This task, as well as these and other objects which will become clearer below, are achieved by a controller interface and the process for assembly thereof according to the attached independent claims.

Detailed characteristic features of a controller interface and the process for assembly thereof according to the invention are contained in the dependent claims.

In particular, according to the present invention, a controller interface, in particular configured to be fixed to a refrigerating machine and to be connected to an interface controller, for operation thereof, comprises:
a screen having a front face and a back face and comprising an operative layer having responsive pads facing the front face and a plurality of first contacts each electronically connected to a respective pad;
an electronic device, or PCB, having a plurality of second contacts for transferring signals from the operative layer to the electronic device;
a frame having an outer part to which the back face of the screen is attachable, for supporting it, and an inner part to which the electronic device is attachable, for supporting it.

The frame has a plurality of through-openings, each corresponding to a first contact of the screen and positioned so that, following coupling together of the screen and frame, each first contact is arranged facing through a corresponding opening.

The screen and the electronic device, therefore, are configured so that each of them has the respective first contacts and second contacts which are such that they face each other when the screen and the electronic device are correctly assembled together with the frame which has the openings which place the first contacts in communication with the second contacts, which may project into the said openings where necessary so as to almost come into direct contact with each other.

In other words, the interface has for each first contact of the screen a corresponding frame opening and a corresponding second contact of the electronic device.

The electronic device may comprise means for being connected to an electrical apparatus which forms part of a machine so that the user may operate said machine by activating the electronic apparatus by means of the interface according to the present invention.

Alternatively, the interface may be incorporated in said electronic apparatus so as to form a controller which constitutes an article attachable to a product so that the screen is accessible for a user and at the same the electronic apparatus is connected to a machine, for example a refrigerator, integrated in said product, in order to operate it or set parameters for operation of the latter.

The interface is configured so that each first contact defines a portion of said back face.

The screen may have a form which extends mainly along a plane.

For constructional simplicity, for example, the back face may be substantially flat and the first contacts may have a contact wall which is flush with the back face or may project therefrom so as to facilitate the electrical connection with the second contacts.

The electronic device is configured so that the second contacts are positioned facing the first contacts through the openings and are placed in electrical contact with said first contacts by a conductive adhesive, making contact therewith through the respective opening of the frame.

In other words, according to the present invention, the electrical connection between the screen and the electronic device is obtained through the frame by means of a conductive adhesive which electrically connects each first contact to the corresponding second contact, possibly sealing them off from each other, namely by realizing a chemical and/or mechanical connection between the conductive adhesive and first contact and second contact, such as to prevent the electrical connection between the first contact and the second from being affected by a possible chemical action, for example oxidation, of the first contact and/or second contact.

In a manner conventional per se, each pad is configured to signal electronically the occurrence of a pressure exerted on the front face at the pad itself. In other words, the pads of the screen are pressure-sensitive such that the screen forms a so-called “touch screen”.

For example, the pads may be formed by a part comprising electronic tracks which define an electric circuit and which are shaped so as to form a closed or open annular trajectory which surrounds an area where the screen may have icons which can be backlit so as to indicate to an operator the function, which by means of interaction with the pads, is activated when the interface is operative.

The pads may be realized in the manner of the sensitive pads of the interface described in Italian patent application 102021000032510 in the name of the same Applicant, or may be realized by means of a distribution of conductive tracks, which may be made by means of silkscreen printing and form a graphics screen which forms a conductive base layer which is transparent and the electrical conductivity of which is substantially the same at each pad in groups of pads.

The conductive adhesive may be a silicone-based adhesive with an electrically conductive metallic material for forming an electrical connection between each first contact and the corresponding second contact.

The screen may comprise, in a manner conventional per se, an overstructure or “overlay” which has an outer surface which defines the front face of the screen and an inner surface, opposite to the outer surface, on which the operative layer is fixed or formed, for example by means of silkscreen printing.

The overstructure may comprise, for example as described in the aforementioned document 102021000032510, across its thickness at least one of the following:
a protective layer, for example made of polycarbonate, which is configured to transmit a touch-generated pressure so as to allow activation of the pads across it;
a diffusion layer, configured to ensure a uniform light radiation which crosses it;
a base layer, which is opaque and provided with portions shaped to form icons, symbols or numbers when they are backlit and which are light-permeable or transparent or perforated and are arranged opposite the sensitive pads.

The screen may comprise a light-impermeable masking layer which covers the inner surface of the overstructure and the operative layer, whereby the masking layer does not cover the first contacts so that they are joined to the second contacts directly by means of the conductive adhesive.

The masking layer may have discontinuities in the shaped portions of the base layer or may consist of the layer.

The first contacts may be arranged adjacent to each other along the back face of the screen, for example along a straight trajectory for constructional simplicity, and the second contacts may be correspondingly positioned on the electronic device in a mirror arrangement with respect to the first contacts.

The conductive adhesive may be divided into portions, each of which places a first contact in contact with a corresponding second contact and is physically and electrically separated from other portions which place additional first contacts in contact with corresponding second contacts so as to avoid electric bridges between non-corresponding first and second contacts, but at the same time sealing off the connection between first contact and second contact such that they are not exposed to the external environment, in order to increase significantly the durability and reliability of the connection itself. In fact, the sealing effect obtained by means of the electric connection between the first and second contacts via the conductive adhesive prevents possible adverse effects, for example oxidation, of said contacts by the surrounding atmosphere in which the interface operates. At the same time, however, the adhesive is elastically deformable so as to ensure the strength of its electrical connection to the first contact and second contact, as well as its intact condition even following stresses which would tend to damage these connections or its intact state, for example following handling of the interface during installation thereof.

The use of an interface according to the invention with a portion of conductive adhesive as described above is therefore able to avoid false contacts or erroneous command signals which would occur if a command signal resulting from the operation of one of the pads were to be transmitted from the first contact of the pad to a second contact which did not actually correspond to the correct second contact, i.e. the second contact which faces the first contact through the opening corresponding to each of then.

A process for manufacturing an interface according to the present invention comprises:
a step A involving the formation of a screen of the interface, an electronic device and a frame apt to connect together the screen and the electronic device; the screen is formed with first contacts exposed on a back face thereof and the electronic device has second contacts which are positioned so as to correspondingly face the first contacts; the frame correspondingly is formed with openings positioned and configured so that, following coupling of the screen and the electronic device to the frame, the first contacts and the second contacts face each other through the said openings;
a step B of applying a conductive adhesive onto the first contacts, second contacts and/or inside the openings;
a step C of coupling the screen and the electronic device to the frame so that the first contacts and the second contacts are fixed together and electrically connected by the conductive adhesive.

In this way, this process allows the electrical connection and at the same time the sealing of the first contacts to the second contacts during fixing of the screen and the electronic device to the frame, simplifying and at the same time making more efficient the process for production of an interface compared to the known conventional solutions.

Step B may involve applying a portion of conductive adhesive onto each first contact, second contact and/or opening.

The portion of conductive adhesive, in the process according to the present invention, may consist of an amount of conductive adhesive which is both:
sufficient for forming an electrical contact between a first contact and the corresponding second contact through a corresponding opening of the frame, following the execution of step C; and
limited so that each portion of conductive adhesive is separated from the other portions so as not to generate electrical contacts between them.

Step C may comprise a step C1 of arranging the electronic device in contact with the frame so that the openings are superimposed on the second contacts, step B being carried out after step C1 and involving the injection, or casting or insertion, into each of the openings, of a portion of conductive adhesive. Step C may also comprise a step C2, following step B, involving superimposing the screen on the frame so that the first contacts are superimposed on the openings inside which they come into contact with the portions of conductive adhesive which connect them electrically to the second contacts, fixing them both to the latter and to the frame itself in an elastically deformable manner.

Alternatively, step C may comprise a step C3 of arranging the screen in contact with the frame so that the openings are superimposed on the first contacts, step B being carried out after step C3 and involving the injection, or casting or insertion, into each of the openings, of a portion of conductive adhesive; step C also comprising a step C4, following step B and involving superimposing the electronic device on the frame so that the second contacts are superimposed on the openings inside which they come into contact with the portions of conductive adhesive which connect them electrically to the first contacts, fixing them both to the latter and to the frame itself in an elastically deformable manner.

Again, alternatively, the portions of conductive adhesive may be positioned inside the openings of the frame before assembly of the latter together with the screen and/or with the electronic device which may be subsequently or simultaneously coupled together.

It is therefore clear how the process according to the present invention is easy and flexible to implement, being able to provide an interface which is strong and resistant even in unfavourable atmospheric conditions.

Further characteristic features and advantages of the invention will emerge more clearly from the description of a preferred, but non-exclusive embodiment of a controller interface and the process for assembly thereof according to the invention, illustrated in an embodiment provided thereof solely by way of a non-limiting example in the attached sets of drawings listed below.

### BRIEF DESCRIPTION OF THE DRAWINGS

FIGS. 1a and 1b show an interface for a controller according to the prior art

FIG. 2 shows in schematic form a plan view of an interface according to the present invention;

FIG. 3 shows in schematic form the interface according to FIG. 2, partially exploded, viewed along the cross-sectional plane III-III of FIG. 2;

FIG. 3 shows in schematic form the interface according to FIG. 2, partially exploded, viewed along the cross-sectional plane IV-IV of FIG. 2;

FIG. 5 shows in schematic form the interface according to FIG. 2, viewed along the cross-sectional plane V-V of FIG. 2;

FIG. 6 shows in schematic form an interface according to the present invention, and the connection of the screen together with the frame and the electronic device, according to a possible embodiment of the present invention;

FIG. 7 shows in schematic form a detail of the interface according to FIG. 6, viewed along the cross-sectional plane VII-VII of FIG. 6.

### DETAILED DESCRIPTION

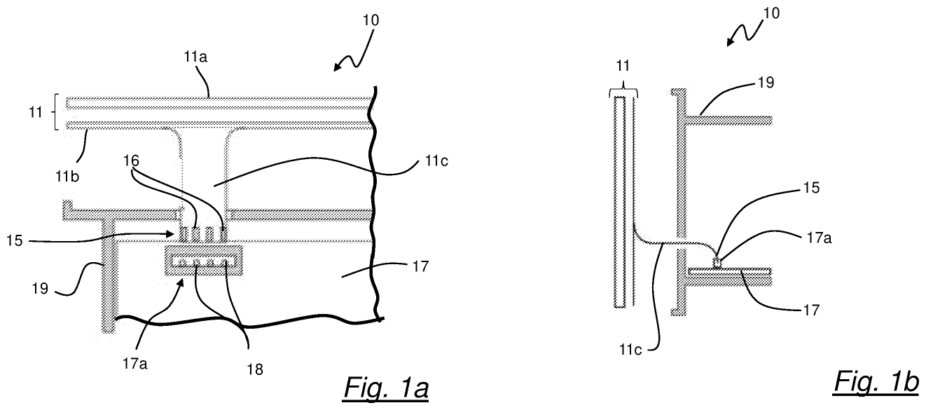

With particular reference to FIGS. 1a and 1b, 10 denotes overall a controller interface of the per se conventional type, comprising: a screen 11 having a front face 11a and a back face 11b and comprising an operative layer 12 provided with responsive pads directed towards the front face 11a which is defined by a protective layer 14.

The screen 11 has a terminal 11c which extends from the back face 11b thereof and which is provided with a plug 15 which has a plurality of first contacts 16 each electronically connected to a respective pad 13.

Each pad is configured to signal electronically the occurrence of a pressure exerted on the front face 11a at the pad itself.

Said interface 10 also comprises an electronic device 17, comprising or consisting of a PCB, is provided with a socket 17a projecting from the body of the electronic device 17 and is provided with a plurality of second contacts 18 designed to be electronically connected to the first contacts 16 in order to transfer signals from the operative layer to the electronic device 15.

The interface 10 also has a frame 19 provided with an outer part to which the back face 11b of the screen 11 is fixed and an inner part to which the electronic device 17 is attachable.

The frame 19 is provided with at least one through-hole which can be crossed by the terminal 11c in order to connect the latter to the socket 17a.

The electrical connection between the first contacts of the terminal 11c and the second contacts of the socket 17a is obtained by means of an interference fit.

The assembly of this interface involves fixing the screen 11 to the frame 19 with the terminal 11c which passes through the hole thereof, then fixing the electronic device 17, or PCB, to the frame 19 and connecting the terminal 11c to the socket 17a.

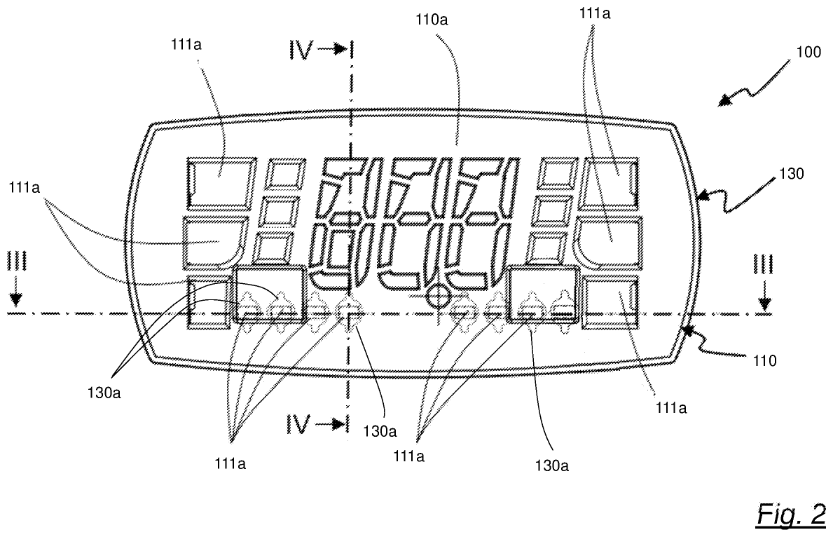

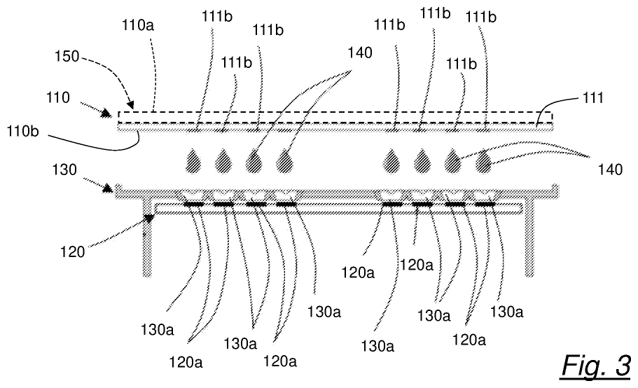

With particular reference to FIGS. 2-7, an interface 100 for a controller according to the present invention comprises:
a screen 110 having a front face 110a and a back face 110b and comprising an operative layer 111 having responsive pads 111a and a plurality of first contacts 11b each electronically connected to a respective pad 111a;
an electronic device 120 having a plurality of second contacts 120a designed to be electronically connected to the first contacts 111b for transferring signals from the operative layer 111 to the electronic device 120;
a frame 130 having an outer part to which the back face 110b of the screen 110 is attachable, for supporting it, and an inner part to which the electronic device 120 is attachable, for supporting it.

The responsive pads 111a are situated facing the front face 110a.

Each pad 111a is configured to signal electronically the occurrence of a pressure exerted on the front face 110a at the pad 111a itself.

The frame 130 has a plurality of through-openings 130a, each corresponding to a first contact 111b of the screen 110 and positioned so that, following coupling together of the screen 110 and frame 130, each first contact 111b is arranged facing through a corresponding opening 130a.

Each first contact 111b defines a portion of the back face 110b which may be substantially flat, or have the first contacts 111b raised so as to project with respect to a portion—moreover flat—of the remainder of the back face 110b.

The electronic device 120 is configured so that the second contacts 120a are positioned facing through the openings 130a.

The interface 100 comprises a conductive adhesive 140 which connects each first contact 111b to the corresponding second contact through the respective opening 130a of the frame 130.

The conductive adhesive 140 may be a silicone-based adhesive filled with an electrically conductive metallic material, for example silver, for forming an electrical connection between each first contact 111b and the corresponding second contact.

The screen 110 may comprise an overstructure 150 which has an outer surface which defines the front face 110a of the screen 110 and an inner surface, opposite to the outer surface, on which the operative layer 111 is formed by means of silkscreen printing.

The screen 110 may comprise a light-impermeable masking layer which covers the inner surface of the overstructure 150 and the operative layer 111, whereby the masking layer does not cover the first contacts 111b so that they are joined to the second contacts 120a directly by means of the conductive adhesive 140.

The first contacts 111b and/or second contacts 120a are configured to project inside the openings 130a following coupling of the screen 110 and the electronic device 120 to the frame 130.

The first contacts 111b may be adjacent to each other on the back face 110b of the screen 110 and the second contacts 120a may be positioned adjacent to each other in a mirror arrangement on the electronic device 120. Accordingly, the conductive adhesive 140 may be divided into portions, each of which places a first contact 11b in contact with a corresponding second contact and is physically and electrically separated from other portions which place additional first contacts 111b in contact with corresponding second contacts 120a.

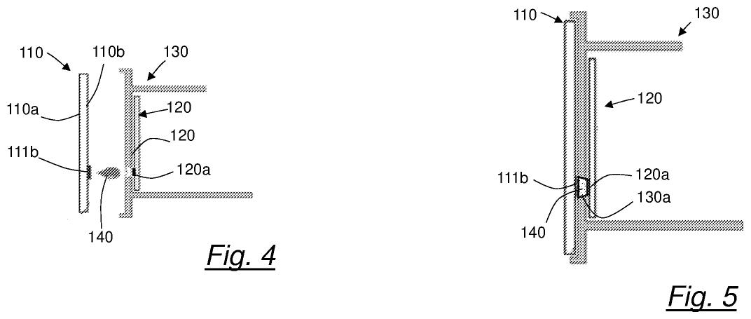

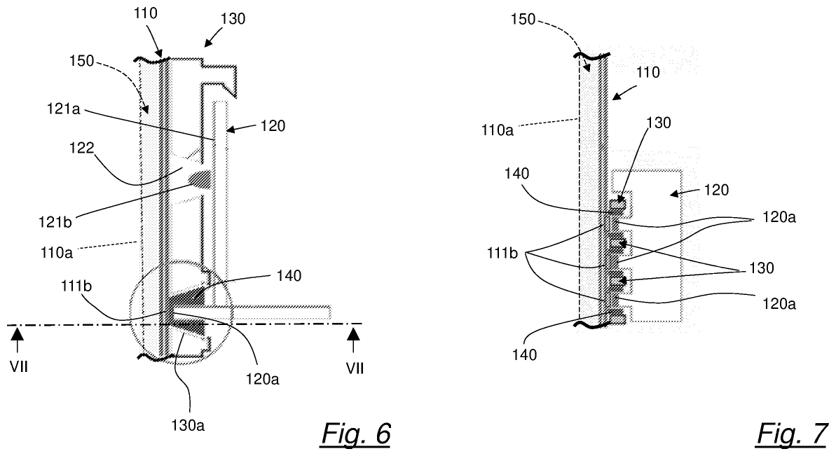

An example of a portion of conductive adhesive 140 is shown in FIG. 5 with a dot-shaded background and in FIGS. 6 and 7.

In particular, FIGS. 6 and 7 shows an example of an embodiment of the present invention in which the electronic device 120 of the interface 100 comprises a first printed circuit board 121 which has an operative wall 121a which extends in a substantially flat manner, parallel to the screen 110, and which is provided with elements 121b for emitting light radiation, for example LEDs.

The frame, in this case, is provided with light channels or guides 122 designed to guide the light of the emitting elements 121b towards the shaped portions, which form icons, symbols or numbers, of the base layer, where present, and towards the pads 11a of the screen in order backlight them.

In other words, for example an interface 100 according to the present invention may have a base layer which defines symbols or icons which are aligned with the pads 11a, through the thickness of the screen 110, and emitting elements 121b of the electronic device, so that they may be backlit by said elements.

Thus, information is provided to the operator regarding the functions which the pads 11a, when operated, are designed to perform, by means of the distinguishing symbols and icons.

In this non-limiting example of embodiment, the second contacts 120a may be provided on a longitudinal end 123a of a second printed circuit board 123 which may be fixed to the first printed circuit board 12 transversely with respect thereto so that the second contacts 120a and the emitting elements 121b project respectively into the openings 130a and the light guides or channels 122.

The present invention also relates to a process for manufacturing an interface 100 which generally comprises:
a step A which involves the formation of a screen 110 of the interface 100, an electronic device 120 and a frame 130 designed to connect together the screen 110 and the electronic device 120, wherein the screen 110 has first contacts 111b exposed on a back face 110b thereof and the electronic device 120 has second contacts 120a which are positioned so as to correspondingly face the first contacts 111b;
a step B of applying a conductive adhesive 140 onto the first contacts 111b, second contacts 120a and/or inside the openings 130a;
a step C of coupling the screen 110 and the electronic device 120 to the frame 130 so that the first contacts 111b and the second contacts 120a are fixed together and electrically connected by the conductive adhesive 140 so as to form an interface 100 according to one of the preceding claims.

Structurally speaking, the frame 130 is made in step A with openings 130a positioned and configured so that, following coupling of the screen 110 and the electronic device 120 to the frame 130, the first contacts 111b and the second contacts 120a face each other through the openings 130a. Correspondingly, the screen 110 and the electronic device 120 are made so that the first contacts 111b and the second contacts 120a are positioned facing each other in a mirror arrangement.

Step B, in an advantageous embodiment of the present invention, may involve applying a portion of conductive adhesive 140 onto each first contact 110 and/or onto each second contact 111b and/or inside each opening 130a.

The portion of conductive adhesive is chosen as an amount of conductive adhesive 140 in such a way that it is both:
sufficient to form an electrical contact between the first contacts 111b and the corresponding second contacts 120a through a corresponding opening 130a of the frame 130, following the execution of step C; and
limited so that each portion of conductive adhesive 140 is separated from the other portions so as not to generate electrical contacts between them.

Step C may, in detail, comprise a step C1 of arranging the electronic device 120 in contact with the frame 130 so that the openings 130a are superimposed on the second contacts 120a.

In order to simplify production, step B may be carried out following step C1 and involves the injection or casting, in each of the openings 130a, of a portion of conductive adhesive 140.

In this case, step C may also comprise a step C2,which is performed after step B and which involves superimposition of the screen 110 on the frame 130 so that the first contacts 111b are superimposed on the openings 130a. This, while making sure that the portion of conductive adhesive 140 consists of an amount of conductive adhesive 140 sufficient to join electrically each first contact 111b with the corresponding second contact facing the same opening 130a.

Step C involves compression of the screen 110 and/or the electronic device 120 on the frame 130 so as to fix them together and/or on the latter by means of the conductive adhesive 140 applied in step B.

In a particularly preferred mode of implementation of the present invention, for the sake of simpler production thereof, the portion of conductive adhesive 140 may be distributed inside the openings 103a of the frame 130 when either the screen 110 or the electronic device 120 is already fixed to the latter so as to apply respectively the electronic device 120 or the screen 110 in such a way that the openings 103a are closed and full of conductive adhesive which seals them, realizing an efficient and protective electrical connection between the first contacts 111b and the second contacts 120a and closing of the completion.

It can therefore be understood how the implementation of the present invention described above achieves the predefined objects and tasks.

In particular an interface 100 of a controller and a process for assembly thereof according to the present invention may therefore be easily realized using known production technology.

Furthermore, an interface 100 and its assembly process, according to the present invention, are structurally simple, easy to use and easily adaptable to the form and dimensions of a product depending on the specific mounting conditions involved.

The conductive adhesive 140 may be chosen, depending on the particular mounting conditions from among the following:
a silicone material mixed with conductive material, for example silicone material with an additive consisting of copper and silver, or copper and aluminium or glass and silver, for example those which are commercially supplied by the company Euro Technologies S.r.l. under the trade codes FIP-SSC, FIP-SSA and SSG, respectively;
an adhesive, for example of the epoxy type with an added conductive material, such as that commercially known under the name of MCS110EP, made by the company Memcom Limited.

The choice between these two solutions may be made depending on the need for elasticity in the association between the first contacts 111b and the second contacts 120a.

In fact, in the case where this association involves an end-to-end connection between the electronic device and the screen, namely in a mutually transverse—for example perpendicular—arrangement, it is more preferable to adopt the first solution resulting in a more elastic connection.

On the other hand, where the electronic device and the screen are substantially parallel, it may be preferably to use a more rigid adhesive, such as an epoxy adhesive.

The invention thus conceived may be subject to numerous modifications and variations, all of which fall within the scope of protection of the attached claims.

Moreover, all the details may be replaced by other technically equivalent elements.

Where the operational characteristics and the techniques mentioned are followed by reference numbers or symbols, these reference numbers or symbols have been assigned with the sole purpose of facilitating understanding of the description and said claims and consequently they do not limit in any way the interpretation of each element which is identified, purely by way of example, by said reference numbers or symbols.

1. Interface (100) for a controller comprising:
a screen (110) having a front face (110a) and a back face (110b) and comprising an operative layer (111) having responsive pads (111a) facing the front face (110a) and a plurality of first contacts (111b) each electronically connected to a respective pad (111a); each pad (111a) being configured to electronically signal the occurrence of a pressure exerted on the front face (110a) at the pad (111a) itself;
an electronic device (120) having a plurality of second contacts (120a) apt to be electronically connected with the first contacts (111b) for transferring signals from the operative layer (111) to the electronic device (120);
a frame (130) having an outer part to which the back face (110b) of the screen (110) is attachable, for supporting it, and an inner part to which the electronic device (120) is attachable, for supporting it;
wherein furthermore
the frame (130) has a plurality of through-openings (130a) each corresponding to a first contact (111b) of the screen (110) and positioned such that, following coupling together of the screen (110) and the frame (130), each first contact (111b) is arranged facing through a corresponding opening (130a);
each first contact (111b) defines a portion of said back face (110b);
the electronic device (120) is configured such that the second contacts (120a) are positioned facing through the openings (130a);
wherein the interface (100) includes a conductive adhesive (140) which connects each first contact (111b) to the corresponding second contact through the respective opening (130a) of the frame (130).

2. Interface (100) according to claim 1, wherein the conductive adhesive (140) is a silicone-based adhesive filled with an electrically conductive metallic material so as to form an electrical connection between each first contact (111b) and the corresponding second contact.

3. Interface (100) according to one of the preceding claims, wherein the screen (110) comprises an overstructure (150) having an outer surface which defines the front face (110a) of the screen (110) and an inner surface, opposite to the outer surface, on which the operative layer (111) is formed by means of silkscreen printing.

4. Interface (100) according to the preceding claim, wherein the screen (110) comprises a light-impermeable masking layer covering the inner surface of the overstructure (150) and the operative layer (111), whereby the masking layer does not cover the first contacts (111b) so that they are joined to the second contacts (120a) directly by means of the conductive adhesive (140).

5. Interface (100) according to one of the preceding claims, wherein the first contacts (111b) and/or second contacts (120a) are configured to project inside the openings (130a) following coupling of the screen (110) and electronic device (120) to the frame (130).

6. Interface (100) according to one of the preceding claims, wherein the first contacts (111b) are adjacent to each other along the back face (110b) of the screen (110) and the second contacts (120a) are positioned adjacent to each other in a mirror arrangement on the electronic device (120), the conductive adhesive (140) being divided into portions each of which places a first contact (111b) in contact with a corresponding second contact and is physically and electrically separated from other portions which place additional first contacts (111b) in contact with corresponding second contacts (120a).

7. Process for manufacturing an interface (100) comprising:
a step A involving the formation of a screen (110) of the interface (100), an electronic device (120) and a frame (130) apt to connect together the screen (110) and the electronic device (120), wherein the screen (110) has first contacts (111b) exposed on a back face (110b) thereof and the electronic device (120) has second contacts (120a) which are positioned so as to correspondingly face the first contacts (111b), the frame (130) having openings (130a) positioned and configured such that, following coupling of the screen (110) and electronic device (120) to the frame (130), the first contacts (111b) and second contacts (120a) face each other through the openings (130a);
a step B of applying a conductive adhesive (140) on the first contacts (111b), second contacts (120a) and/or inside the openings (130a);
a step C of coupling the screen (110) and the electronic device (120) to the frame (130) such that the first contacts (111b) and second contacts (120a) are fixed together and electrically connected by the conductive adhesive (140), so as to form an interface (100) according to one of the preceding claims.

8. Process according to the preceding claim, wherein step B involves applying a portion of conductive adhesive (140) onto each first contact (111b), second contact and/or opening (130a), wherein said portion consists of an amount of conductive adhesive (140) sufficient for forming an electrical contact between a first contact (111b) and the corresponding second contact through a corresponding opening (130a) of the frame (130) following the execution of step C; wherein said amount of conductive adhesive (140) is limited such that each portion of conductive adhesive (140) is separated from the other portions so as not to generate electrical contacts between them.

9. Process according to either one of claims 7 and 8, wherein step C comprises a step C1 of arranging the electronic device (120) in contact with the frame (130) such that the openings (130a) are superimposed on the second contacts (120a); wherein said step B is carried out after step C1 and comprises the injection, into each of the openings (130a), of a portion of conductive adhesive (140); wherein step C further comprises a step C2,carried out after step B and involving superimposing the screen (110) on the frame (130) such that the first contacts (111b) are superimposed on the openings (130a); wherein said portion of conductive adhesive (140) consists of an amount of conductive adhesive (140) sufficient to electrically join each first contact (111b) with the corresponding second contact facing the same opening (130a).

10. Process according to one of claims 7 to 9, wherein step C involves compressing the screen (110) and/or the electronic device (120) onto the frame (130) so as to secure them together and/or onto the latter by means of the conductive adhesive (140) applied in step B.
